(19) United States
(12) Patent Application Publication
(10) Pub. No.: US 2026/0305264 A1
(43) Pub. Date: Oct. 1, 2026

(54) POLISHING METHOD AND POLISHING APPARATUS

(71) Applicant: EBARA CORPORATION, Tokyo (JP)

(72) Inventors: Toshimitsu SASAKI, Tokyo (JP); Keita YAGI, Tokyo (JP); Raksha ZANWAR, Tokyo (JP); Ching Wei HUANG, Tokyo (JP)

(21) Appl. No.: 19/397,657

(22) Filed: Nov. 21, 2025

(30) Foreign Application Priority Data
Nov. 29, 2024 (JP) 2024-208190

(51) Int. Cl. H10P 74/00; B24B 37/013; B24B 37/20; B24B 49/16; H10P 52/40

(52) U.S. Cl. CPC H10P 74/238; B24B 37/013; B24B 37/20; B24B 49/16; H10P 52/403; H10P 52/407

(57) ABSTRACT

A technique capable of stabilizing pressure control of a polishing head when a polishing rate changes significantly during polishing of a workpiece, such as a wafer, is disclosed. A polishing method includes during polishing of the workpiece, calculating a plurality of polishing rates of a plurality of regions within the surface of the workpiece; and detecting a plurality of change points of the plurality of polishing rates. Before the plurality of change points of the plurality of polishing rates are detected, the polishing head performs a polishing-amount control operation of polishing the plurality of regions of the workpiece by the same polishing amount. After the plurality of change points of the plurality of polishing rates are detected, the polishing head performs a profile control operation of polishing the plurality of regions of the workpiece such that a film-thickness profile of the workpiece reaches a target film-thickness profile.

### CROSS REFERENCE TO RELATED APPLICATION

This document claims priority to Japanese Patent Application No. 2024-208190 filed Nov. 29, 2024, the entire contents of which are hereby incorporated by reference.

### BACKGROUND

Manufacturing process of a semiconductor device includes various processes, such as a process of polishing a dielectric film, such as SiO₂, and a process of polishing a metal film, such as copper or tungsten. Polishing of a wafer is performed using a polishing apparatus. The polishing apparatus generally includes a polishing table that supports a polishing pad, a polishing head that presses the wafer against the polishing pad, and a slurry supply nozzle that supplies slurry onto the polishing pad. While the polishing table is rotated, the slurry is supplied onto the polishing pad on the polishing table, and the polishing head presses the wafer against the polishing pad. The wafer is in sliding contact with the polishing pad in the presence of the slurry. A surface of the wafer is planarized by a combination of a chemical action of the slurry and a mechanical action of the polishing pad and abrasive grains contained in the slurry.

The polishing head has a plurality of pressure chambers corresponding to a plurality of regions of the wafer. During polishing of the wafer, these pressure chambers are filled with compressed gas (for example, compressed air), and the internal pressure of the pressure chambers is applied to the wafer. During polishing of the wafer, a film thickness of the wafer is measured by a film-thickness sensor, so that a current film-thickness profile of the wafer is obtained. The pressure in each pressure chamber of the polishing head is controlled so that the current film-thickness profile reaches a target film-thickness profile.

When a polishing-target film of the wafer is a metal film, such as copper, the metal film may react with oxygen in the air before polishing of the wafer, and as a result, a natural oxide film may be formed on the metal film over time. This natural oxide film coexists in equilibrium with the metal film and has high thermal and structural stability.

When the metal film covered with the natural oxide film is polished by the polishing apparatus described above, the natural oxide film is more difficult to be polished than the metal film. Specifically, a polishing rate (also referred to as a removal rate) of the natural oxide film is typically lower than a polishing rate of the metal film. In such a case, the pressures in the pressure chambers of the polishing head become high in order to increase the polishing rate of the natural oxide film. Thereafter, when the natural oxide film is removed, the metal film is then polished with a significantly different polishing rate. As a result, the pressures in the pressure chambers rapidly decrease, thus causing hunting (large fluctuations) of the pressures in the pressure chambers, which causes unstable pressure control in the pressure chambers. A similar problem may occur when the surface of the wafer is composed of a laminated structure made of different materials.

### SUMMARY

Accordingly, there is provided a technique capable of stabilizing pressure control of a polishing head when a polishing rate changes significantly during polishing of a workpiece, such as a wafer.

Embodiments, which will be described below, relate to a technique for polishing a workpiece, such as a wafer, a circular substrate, or a quadrilateral substrate, and more particularly relates to a technique for changing a polishing control operation based on a polishing rate of the workpiece.

In an embodiment, there is provided a polishing method comprising: polishing a workpiece by pressing a surface of the workpiece against a polishing pad with a plurality of pressure chambers of a polishing head while measuring a film thickness of the workpiece; during polishing of the workpiece, calculating a plurality of polishing rates of a plurality of regions within the surface of the workpiece; and detecting a plurality of change points of the plurality of polishing rates, wherein, before the plurality of change points of the plurality of polishing rates are detected, the polishing head performs a polishing-amount control operation of polishing the plurality of regions of the workpiece by the same polishing amount, and wherein, after the plurality of change points of the plurality of polishing rates are detected, the polishing head performs a profile control operation of polishing the plurality of regions of the workpiece such that a film-thickness profile of the workpiece reaches a target film-thickness profile.

In an embodiment, the polishing-amount control operation includes polishing the plurality of regions of the workpiece by the polishing head such that a surface shape of the workpiece, indicated by an initial film-thickness profile at a start of polishing of the workpiece, is maintained.

In an embodiment, the plurality of change points of the plurality of polishing rates are detected when at least one of a first detection condition and a second detection condition is satisfied, the first detection condition is that each of the plurality of polishing rates reaches a reference rate, and the second detection condition is that a polishing amount of each of the plurality of regions of the workpiece reaches a reference polishing amount.

In an embodiment, the polishing-amount control operation is switched to the profile control operation after all of the plurality of change points of the plurality of polishing rates, corresponding respectively to the plurality of regions of the workpiece, are detected.

In an embodiment, the workpiece has a surface structure including a first film and a second film formed under the first film, and the plurality of change points are points in time at which the first film is removed.

In an embodiment, a polishing rate of the first film is different from a polishing rate of the second film.

In an embodiment, there is provided a polishing apparatus comprising: a polishing table configured to support a polishing pad; a polishing head having a plurality of pressure chambers configured to press a surface of a workpiece against the polishing pad; a film-thickness sensor configured to measure a film thickness of the workpiece; a pressure regulating device configured to regulate pressures in the plurality of pressure chambers; and a polishing controller configured to perform pressure control of the polishing head by controlling operation of the pressure regulating device, wherein the polishing controller is configured to: calculate a plurality of polishing rates of a plurality of regions within the surface of the workpiece; detect a plurality of change points of the plurality of polishing rates; before detecting the plurality of change points of the plurality of polishing rates, instruct the pressure regulating device to cause the polishing head to perform a polishing-amount control operation of polishing the plurality of regions of the workpiece by the same polishing amount; and after detecting the plurality of change points of the plurality of polishing rates, instruct the pressure regulating device to cause the polishing head to perform a profile control operation of polishing the plurality of regions of the workpiece such that a film-thickness profile of the workpiece reaches a target film-thickness profile.

In an embodiment, the polishing controller is configured to: create an initial film-thickness profile at a start of polishing of the workpiece from a plurality of measurement values of an initial film thickness of the workpiece; and during the polishing-amount control operation, instruct the pressure regulating device to cause the polishing head to polish the plurality of regions of the workpiece such that a surface shape of the workpiece, indicated by the initial film-thickness profile, is maintained.

In an embodiment, the polishing controller is configured to detect the plurality of change points of the plurality of polishing rates when at least one of a first detection condition and a second detection condition is satisfied, the first detection condition is that each of the plurality of polishing rates reaches a reference rate, and the second detection condition is that a polishing amount of each of the plurality of regions of the workpiece reaches a reference polishing amount.

In an embodiment, the polishing controller is configured to switch the pressure control of the polishing head from the polishing-amount control operation to the profile control operation after all of the plurality of change points of the plurality of polishing rates, corresponding respectively to the plurality of regions of the workpiece, are detected.

In an embodiment, the workpiece has a surface structure including a first film and a second film formed under the first film, and the plurality of change points are points in time at which the first film is removed.

In an embodiment, a polishing rate of the first film is different from a polishing rate of the second film.

Before the change point of the polishing rate is detected, the profile control operation is not performed, and the polishing-amount control operation is performed. This polishing-amount control operation is a quantitative polishing operation in which a plurality of regions of the workpiece are polished with the same polishing amount. During the polishing-amount control operation, the surface shape of the workpiece is maintained, and therefore changes in pressure in the plurality of pressure chambers of the polishing head are small. The change point of the polishing rate means that the first film constituting an exposed surface of the workpiece has been removed and that the second film made of material different from that of the first film has been exposed. Polishing of the second film is performed based on the profile control operation until a target film thickness of the workpiece is reached. Therefore, during the profile control operation, since the same material of the second film is removed, the polishing rate does not change significantly. As a result, the profile control operation, i.e., pressure control on the polishing head, can be stabilized.

### BRIEF DESCRIPTION OF THE DRAWINGS

FIG. 1 is a schematic diagram illustrating an embodiment of a polishing apparatus;

FIG. 2 is a cross-sectional view illustrating an embodiment of a polishing head;

FIG. 3 is a cross-sectional view illustrating an example of a surface structure of a workpiece before being polished;

FIG. 4 is a flowchart illustrating an embodiment of a method for polishing a workpiece;

FIG. 5 is a graph illustrating changes in a film-thickness profile of a workpiece polished by a polishing method performed in accordance with the embodiment shown in FIG. 4;

FIG. 6 is a graph illustrating changes in polishing rates corresponding to the embodiment shown in FIG. 5;

FIG. 7 is a graph illustrating a change in film-thickness profile of a workpiece polished by a polishing method that performs only a profile control operation;

FIG. 8 is a graph illustrating changes in polishing rates corresponding to the comparative example shown in FIG. 7; and

FIG. 9 is a flowchart illustrating an embodiment of detecting a plurality of change points of a plurality of polishing rates.

### DESCRIPTION OF EMBODIMENTS

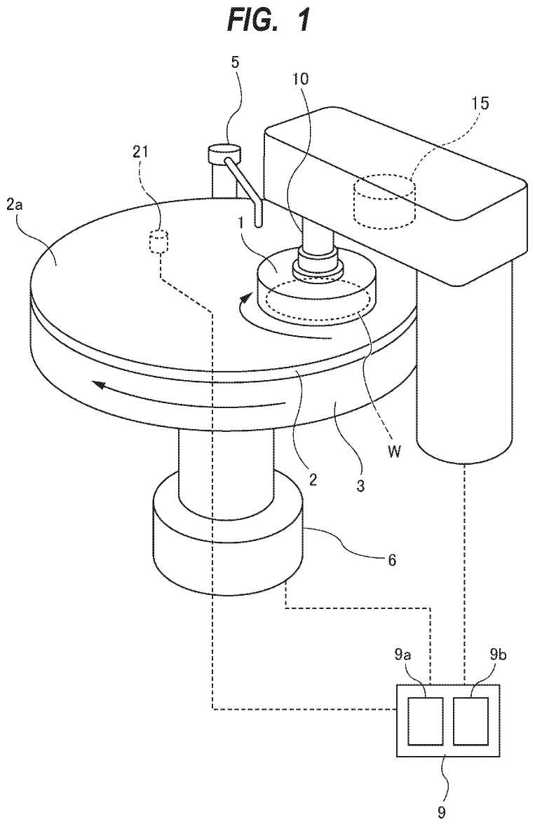

Hereinafter, embodiments will be described with reference to the drawings. FIG. 1 is a schematic diagram illustrating an embodiment of a polishing apparatus. As shown in FIG. 1, the polishing apparatus includes a polishing table 3 configured to support a polishing pad 2, a polishing head 1 configured to press a workpiece W against the polishing pad 2, a table motor 6 configured to rotate the polishing table 3, a polishing-liquid supply nozzle 5 configured to supply a polishing liquid, such as slurry, onto the polishing pad 2, and a polishing controller 9 configured to control operation of the polishing apparatus. An upper surface of the polishing pad 2 constitutes a polishing surface 2a for polishing the workpiece W.

The polishing head 1 is coupled to a head shaft 10, which is coupled to a polishing-head rotating device 15. The polishing-head rotating device 15 is configured to rotate the polishing head 1 together with the head shaft 10 in a direction indicated by arrow. The configuration of the polishing-head rotating device 15 is not particularly limited, but in one example, the polishing-head rotating device 15 may include an electric motor, a belt, and pulleys. The polishing table 3 is coupled to the table motor 6, which is configured to rotate the polishing table 3 and the polishing pad 2 in a direction indicated by arrow. The polishing head 1, the polishing-head rotating device 15, and the table motor 6 are coupled to the polishing controller 9 so that operations of the polishing head 1, the polishing-head rotating device 15, and the table motor 6 are controlled by the polishing controller 9.

The workpiece W is polished as follows. While the table motor 6 and the polishing-head rotating device 15 rotate the polishing table 3 and the polishing head 1 in the directions indicated by arrows in FIG. 1, the polishing liquid is supplied from the polishing-liquid supply nozzle 5 onto the polishing surface 2a of the polishing pad 2 on the polishing table 3. The workpiece W, which is being rotated by the polishing head 1, is pressed by the polishing head 1 against the polishing surface 2a of the polishing pad 2 in the presence of the polishing liquid on the polishing pad 2. The surface of the workpiece W is polished by a chemical action of the polishing liquid and a mechanical action of the polishing pad 2 and/or abrasive grains contained in the polishing liquid.

The polishing controller 9 includes a memory 9a in which a program is stored, and an arithmetic device 9b that executes calculations in accordance with instructions included in the program. The polishing controller 9 is composed of at least one computer. The memory 9a includes a main memory, such as random access memory (RAM), and an auxiliary memory, such as a hard disk drive (HDD) or a solid state drive (SSD). Examples of the arithmetic device 9b include a CPU (central processing unit) and a GPU (graphics processing unit). However, the specific configuration of the polishing controller 9 is not limited to these examples.

The polishing apparatus further includes a film-thickness sensor 21 configured to measure a film thickness of the workpiece W on the polishing pad 2. The film-thickness sensor 21 is fixed to the polishing table 3 and rotates together with the polishing table 3. The position of the film-thickness sensor 21 is such that the film-thickness sensor 21 traverses the surface of the workpiece W on the polishing pad 2 each time the polishing table 3 and the polishing pad 2 make one rotation. The film-thickness sensor 21 is configured to measure film thicknesses at a plurality of measurement points on the surface of the workpiece W each time the film-thickness sensor 21 sweeps across the surface of the workpiece W. Specific examples of the film-thickness sensor 21 include an optical film-thickness sensor and an eddy-current film-thickness sensor. However, the type of the film-thickness sensor 21 is not particularly limited as long as the film-thickness sensor 21 can measure the film thickness of the workpiece W. The film-thickness sensor 21 is electrically coupled to the polishing controller 9, and a measured value of film thickness is transmitted from the film-thickness sensor 21 to the polishing controller 9. The measured value of film thickness may be numerical value directly indicating the film thickness, or may be index value or physical quantity indirectly indicating the film thickness.

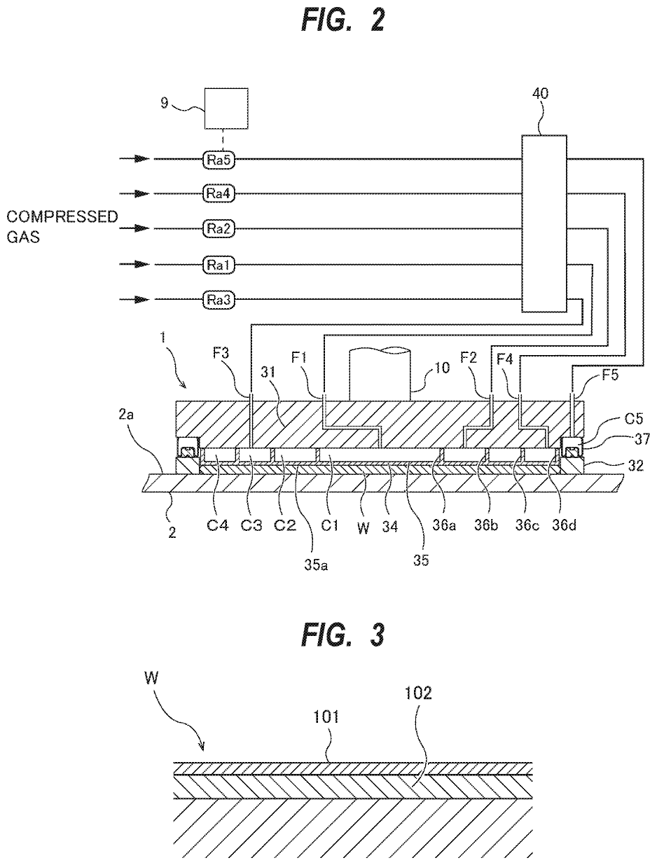

FIG. 2 is a cross-sectional view illustrating an embodiment of the polishing head 1. The polishing head 1 includes a carrier 31 fixed to an end portion of the head shaft 10, an elastic membrane 34 attached to a lower portion of the carrier 31, and a retainer ring 32 disposed below the carrier 31. The retainer ring 32 is disposed around the elastic membrane 34.

The elastic membrane 34 includes a contact portion 35 having a contact surface 35a capable of contacting an upper surface of the workpiece W, and inner wall portions 36a, 36b, 36c and an outer wall portion 36d coupled to the contact portion 35. The contact portion 35 has substantially the same size and the same shape as the upper surface of the workpiece W. The inner wall portions 36a, 36b, and 36c and the outer wall portion 36d are endless walls arranged concentrically. The outer wall portion 36d is located outside the inner wall portions 36a, 36b, and 36c and is arranged so as to surround the inner wall portions 36a, 36b, and 36c.

A plurality of (four in this embodiment) pressure chambers C1, C2, C3, and C4 are provided between the elastic membrane 34 and the carrier 31. The pressure chambers C1, C2, C3, and C4 are formed by the contact portion 35, the inner wall portions 36a, 36b, 36c, and the outer wall portion 36d of the elastic membrane 34. In this embodiment, the elastic membrane 34 forms the four pressure chambers C1 to C4, while, in one embodiment, the elastic membrane 34 may form three pressure chambers, or may form five or more pressure chambers.

An annular membrane (or a rolling diaphragm) 37 is disposed between the carrier 31 and the retainer ring 32, and a pressure chamber C5 is formed inside the membrane 37. Gas delivery lines F1, F2, F3, F4, and F5 are coupled to the pressure chambers C1, C2, C3, C4, and C5, respectively. The gas delivery lines F1, F2, F3, F4, and F5 extend via a rotary joint 40 attached to the head shaft 10.

The gas delivery lines F1, F2, F3, F4, and F5 are coupled to a compressed-gas supply source (not shown) serving as a utility supply source provided in a factory in which the polishing apparatus is installed. Compressed gas, such as compressed air, is supplied to the pressure chambers C1, C2, C3, C4, and C5 through the gas delivery lines F1, F2, F3, F4, and F5, respectively.

Pressure regulators Ra1, Ra2, Ra3, Ra4, and Ra5, which are pressure regulating devices, are attached to the gas delivery lines F1, F2, F3, F4, and F5, respectively. The compressed gas from the compressed-gas supply source is independently supplied into the pressure chambers C1 to C5 through the pressure regulators Ra1 to Ra5 and the gas delivery lines F1 to F5. The pressure regulators Ra1 to Ra5 are configured to regulate the pressures of the compressed gas in the pressure chambers C1 to C5.

The pressure regulators Ra1 to Ra5, which are pressure regulating devices, are coupled to the polishing controller 9. Operations of the pressure regulators Ra1 to Ra5 are controlled by the polishing controller 9. The polishing controller 9 transmits pressure command values for the pressure chambers C1 to C5 to the pressure regulators Ra1 to Ra5, and the pressure regulators Ra1 to Ra5 operate such that the pressures in the pressure chambers C1 to C5 are maintained at the corresponding pressure command values.

The pressure regulators Ra1 to Ra5 are capable of independently changing the pressures in the pressure chambers C1 to C5. Accordingly, the polishing head 1 can independently regulate or adjust polishing pressures applied to corresponding four regions of the workpiece W, namely, a central portion, an inner intermediate portion, an outer intermediate portion, and an edge portion, as well as a pressing force of the retainer ring 32 against the polishing surface 2a of the polishing pad 2. For example, the polishing head 1 can press the different regions of the surface of the workpiece W against the polishing surface 2a of the polishing pad 2 with different polishing pressures. Accordingly, the polishing head 1 can control a film-thickness profile of the workpiece W to achieve a target film-thickness profile.

FIG. 3 is a cross-sectional view illustrating an example of a surface structure of the workpiece W before being polished. As illustrated in FIG. 3, the workpiece W before being polished has a surface structure including a first film 101 and a second film 102, wherein the second film 102 is formed under the first film 101. Examples of the workpiece W include a wafer, a substrate, an interconnect substrate, a quadrilateral substrate, and the like for use in manufacturing semiconductor devices. In the present embodiment, the second film 102 is a metal film, and the first film 101 is a natural oxide film covering the second film 102. The natural oxide film is formed by reaction of the metal film (for example, a copper film) with oxygen in the air. The first film 101 has a uniform thickness over the entire surface of the workpiece W.

However, the second film 102 is not limited to the metal film. In another example, the second film 102 may be a dielectric film. In particular, when the first film 101 is a low dielectric constant film (low-k film), a polishing rate of the first film 101 may be lower than that of the dielectric film (e.g., SiO₂) of the second film 102.

In still another example, the first film 101 is a metal film made of a first metal, and the second film 102 is a metal film made of a second metal different from the first metal.

In still another example, the polishing rate of the first film 101 may be higher than the polishing rate of the second film 102.

In any of the examples described above, the polishing rate (which may be referred to as a removal rate) of the first film 101 is different from the polishing rate of the second film 102. Here, the polishing rate is a film thickness reduced by polishing per unit time.

The film-thickness sensor 21 illustrated in FIG. 1 measures film thicknesses at a plurality of measurement points on the surface of the workpiece W during polishing of the workpiece W, and transmits a plurality of measurement values of the film thickness obtained to the polishing controller 9. The polishing controller 9 is configured to create a current film-thickness profile of the workpiece W from the plurality of measurement values of the film thickness. The film-thickness profile is a distribution of film thickness in a radial direction of the workpiece W.

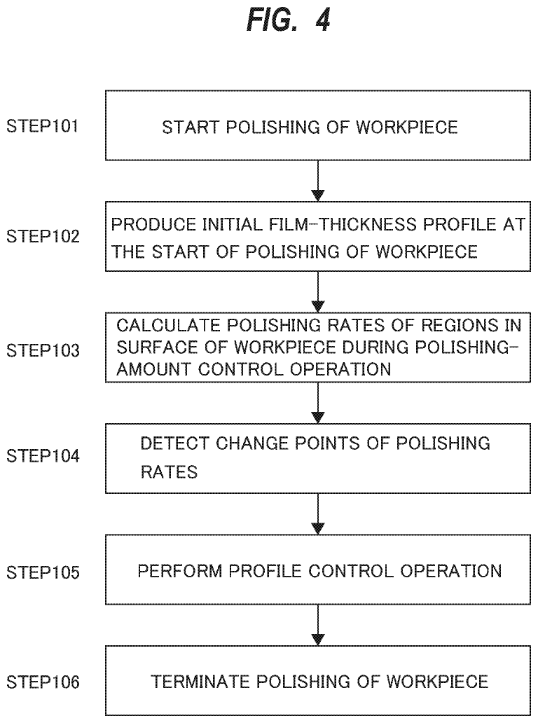

Next, an embodiment of a method of polishing the workpiece W using the polishing apparatus described above will be described. FIG. 4 is a flowchart illustrating an embodiment of a method of polishing the workpiece W.

In step 101, polishing of the workpiece W is started by pressing the surface of the workpiece W against the polishing pad 2 with the plurality of pressure chambers C1, C2, C3, and C4 of the polishing head 1. During polishing of the workpiece W, the film thickness of the workpiece W is measured by the film-thickness sensor 21, and the measurement values of the film thickness of the workpiece W are transmitted to the polishing controller 9.

In step 102, the polishing controller 9 creates an initial film-thickness profile of the workpiece W at the start of polishing of the workpiece W. More specifically, the polishing controller 9 creates the initial film-thickness profile of the workpiece W from a plurality of measurement values of an initial film thickness of the workpiece W at the start of polishing. The initial film thickness of the workpiece W is the film thickness at the time when polishing of the workpiece W is started. Therefore, the initial film-thickness profile is a film-thickness profile at the time when polishing of the workpiece W is started. After polishing of the workpiece W is started, the polishing controller 9 periodically creates a film-thickness profile from a plurality of measurement values of the film thickness of the workpiece W, as well as the initial film-thickness profile.

In step 103, the polishing head 1 performs a polishing-amount control operation. This polishing-amount control operation is a quantitative polishing operation which includes polishing a plurality of regions of the workpiece W by the same polishing amount. Specifically, the polishing controller 9 instructs the pressure regulators Ra1 to Ra4 (see FIG. 2), which are pressure regulating devices, to cause the polishing head 1 to polish the plurality of regions of the workpiece W by the same polishing amount. The plurality of regions of the workpiece W are regions corresponding to the plurality of pressure chambers C1, C2, C3, and C4 (see FIG. 2) of the polishing head 1. Specifically, the polishing head 1 polishes the surface of the workpiece W by applying the pressures in the plurality of pressure chambers C1, C2, C3, and C4 to the plurality of regions of the workpiece W.

The polishing-amount control operation includes polishing the plurality of regions of the workpiece W by the polishing head 1 to maintain a surface shape of the workpiece W indicated by the initial film-thickness profile. Specifically, in the polishing-amount control operation, the polishing controller 9 instructs the pressure regulators Ra1 to Ra4 (see FIG. 2), which are pressure regulating devices, to cause the polishing head 1 to polish the plurality of regions of the workpiece W such that the surface shape of the workpiece W indicated by the initial film-thickness profile is maintained. Specifically, the pressure regulators Ra1 to Ra4 regulate the pressures in the plurality of pressure chambers C1, C2, C3, and C4 of the polishing head 1 such that the surface shape of the workpiece W indicated by the initial film-thickness profile is maintained. Therefore, during the polishing-amount control operation, while the overall film thickness of the workpiece W decreases, the surface shape of the workpiece W is kept constant. Since the surface shape of the workpiece W is maintained during the polishing-amount control operation, changes in pressure in the plurality of pressure chambers C1, C2, C3, and C4 of the polishing head 1 are small.

At the same time as the polishing-amount control operation is started, the polishing controller 9 calculates a plurality of polishing rates of the plurality of regions within the surface of the workpiece W. During the polishing-amount control operation, since the plurality of regions of the workpiece W are polished with the same polishing amount, the plurality of polishing rates of the plurality of regions of the workpiece W are constant.

In step 104, the polishing controller 9 detects a plurality of change points of the plurality of polishing rates. A method of detecting a change point of each polishing rate will be described later, while in one embodiment, a point in time at which the polishing rate of each region of the workpiece W reaches a reference rate is a change point of that polishing rate. The polishing rate changes significantly when the surface structure of the workpiece W changes. In the example illustrated in FIG. 3, a change point of the polishing rate is a point at which the first film 101 constituting an exposed surface of the workpiece W is removed and the second film 102 made of a material different from that of the first film 101 is exposed.

In step 105, after the plurality of change points of the plurality of polishing rates are detected, a profile control operation is performed. The profile control operation is a feedback polishing operation in which the plurality of regions of the workpiece W are polished by the polishing head 1 such that the film-thickness profile of the workpiece W reaches a target film-thickness profile. During the profile control operation, the polishing controller 9 creates a film-thickness profile (i.e., a current film-thickness profile) from a plurality of measurement values of the film thickness sent from the film-thickness sensor 21.

The polishing controller 9 determines pressures in the plurality of pressure chambers C1, C2, C3, and C4 for minimizing a difference between the current film-thickness profile and the target film-thickness profile, and transmits command values of the determined pressures to the pressure regulators Ra1 to Ra4, so that the pressure regulators Ra1 to Ra4 regulate the pressures in the plurality of pressure chambers C1, C2, C3, and C4 of the polishing head 1 in accordance with the command values of the pressures. Such pressure control of the polishing head 1 allows the film-thickness profile of the workpiece W to approach the target film-thickness profile. The target film-thickness profile is stored in advance in the memory 9a of the polishing controller 9. As one embodiment of the profile control operation, a known technique, for example, a technique disclosed in Japanese Patent Application Laid-Open No. 2015-168015, can be applied.

In step 106, when the target film thickness of the workpiece W is reached, the profile control operation is terminated. Polishing of the workpiece W is terminated when the target film thickness is reached or when the second film 102 is completely removed.

Detection of the change point of the polishing rate indicates that the first film 101 constituting an exposed surface of the workpiece W has been removed and polishing of the second film 102 made of a material different from that of the first film 101 has been started. Polishing of the second film 102 is performed based on the profile control operation until the target film thickness of the workpiece W is reached. During the profile control operation, since the same material of the second film 102 is removed, the polishing rate does not change significantly. As a result, the profile control operation, i.e., pressure control of the polishing head 1, can be stabilized.

If the pressure control of the polishing head 1 is switched from the polishing-amount control operation to the profile control operation when a part of the first film 101 remains on the workpiece W, the profile control operation tends to be unstable when the remaining portion of the first film 101 is removed and the second film 102 is exposed. In view of this, in one embodiment, the polishing controller 9 is configured to switch the pressure control of the polishing head 1 from the polishing-amount control operation to the profile control operation after all of the plurality of change points of the plurality of polishing rates corresponding to the plurality of regions of the workpiece W are detected. With such an operation, the profile control operation is started after the entire first film 101 is removed from the workpiece W. As a result, stability of the profile control operation is ensured.

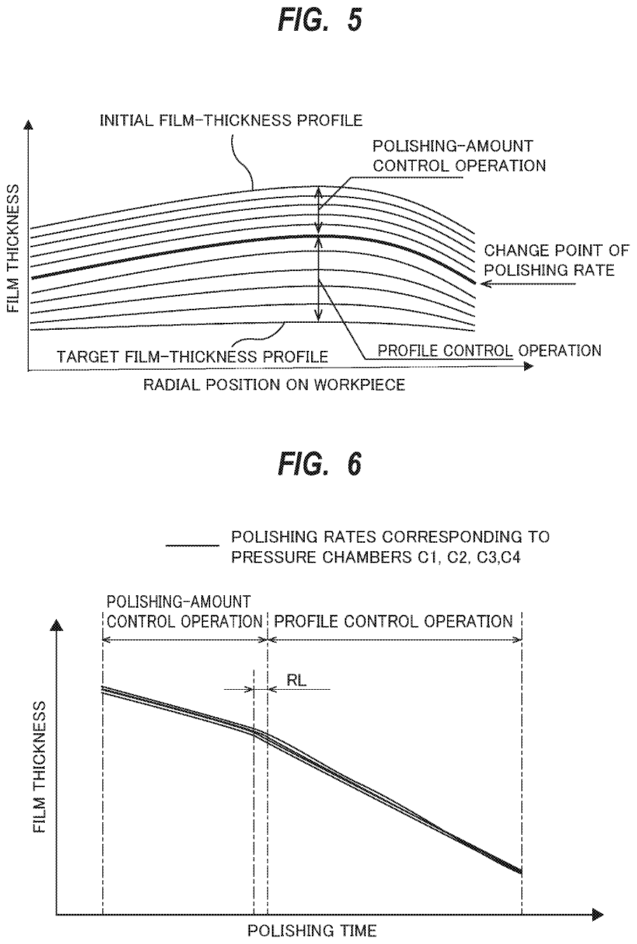

FIG. 5 is a graph illustrating the change in the film-thickness profile of the workpiece W when polished by the polishing method executed in accordance with the embodiment illustrated in FIG. 4. In FIG. 5, a vertical axis represents the film thickness of the workpiece W, and a horizontal axis represents a position in the radial direction of the workpiece W. A plurality of curves illustrated in FIG. 5 are film-thickness profiles that change with polishing time. As illustrated in FIG. 5, as the workpiece W is polished, the film-thickness profile changes from the initial film-thickness profile to the target film-thickness profile.

From the start of polishing of the workpiece W until the change point of the polishing rate is detected, the polishing-amount control operation is performed. As can be seen from FIG. 5, during the polishing-amount control operation, the film thickness of the workpiece W decreases, but the shape of the film-thickness profile, i.e., the surface shape of the workpiece W, does not change.

When the plurality of polishing rates of the plurality of regions of the workpiece W reach their change points, the pressure control of the polishing head 1 is switched from the polishing-amount control operation to the profile control operation. The profile control operation is continued until the target film thickness is reached.

FIG. 6 is a graph illustrating the change in polishing rates corresponding to the embodiment of FIG. 5. In FIG. 6, a vertical axis represents the film thickness of the workpiece W, and a horizontal axis represents the polishing time of the workpiece W. A symbol RL illustrated in FIG. 6 represents a range of time points in which the plurality of change points of polishing rates of the plurality of regions of the workpiece W corresponding to the pressure chambers C1 to C4 are detected. Specifically, the plurality of change points of the plurality of polishing rates fall within the range RL. In the present embodiment, after all of the plurality of change points of the plurality of polishing rates of the plurality of regions of the workpiece W are detected, the pressure control of the polishing head 1 is switched from the polishing-amount control operation to the profile control operation. As illustrated in FIG. 6, the plurality of polishing rates during the profile control operation are maintained substantially constant without hunting.

The polishing rates before the plurality of change points of the plurality of polishing rates are detected are polishing rates of the first film 101 illustrated in FIG. 3, and the polishing rates after the plurality of change points of the plurality of polishing rates are detected are polishing rates of the second film 102 illustrated in FIG. 3. In the embodiment illustrated in FIG. 6, the polishing rate of the first film 101 is lower than the polishing rate of the second film 102 (i.e., a slope angle of the polishing rate of the first film 101 is smaller than a slope angle of the polishing rate of the second film 102).

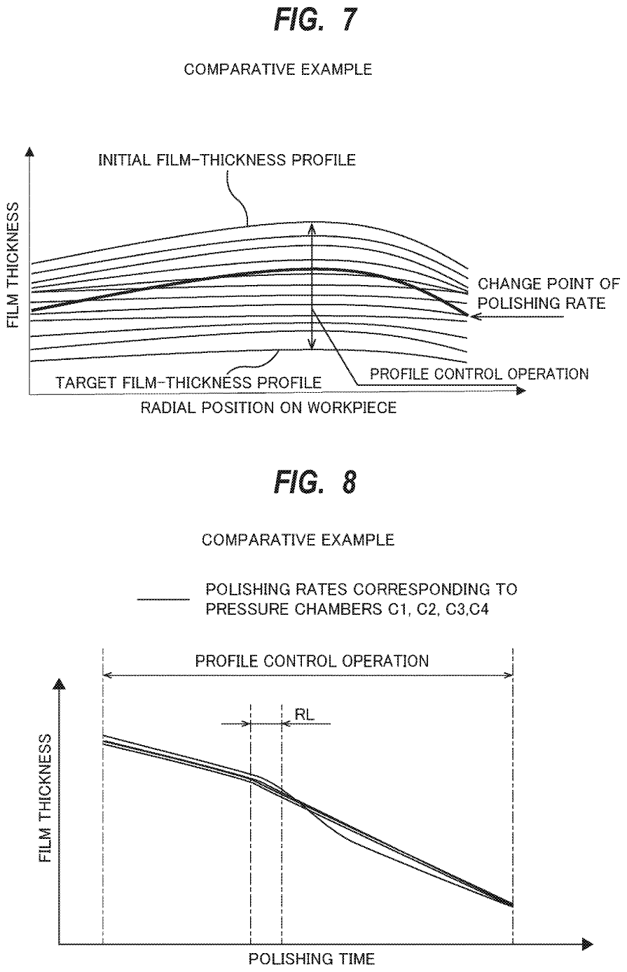

FIG. 7 is a graph illustrating a comparative example, and more specifically, is a graph illustrating a change in a film-thickness profile of the workpiece W polished by a polishing method that performs only the profile control operation. In this comparative example, the profile control operation is performed from the start of polishing of the workpiece W to the polishing end point, and the polishing-amount control operation is not performed. As illustrated in FIG. 7, from the start of polishing of the workpiece W until a change point of the polishing rate is detected, the plurality of regions of the workpiece W are polished non-uniformly. This is because a pressure in a certain pressure chamber changes significantly in order to bring the initial film-thickness profile closer to the target film-thickness profile.

FIG. 8 is a graph illustrating changes in polishing rates corresponding to the comparative example of FIG. 7. As illustrated in FIG. 8, although time points at which change points of polishing rates of the plurality of regions of the workpiece W corresponding to the pressure chambers C1 to C4 are detected fall within the range RL, it can be seen that the range RL illustrated in FIG. 8 is larger than the range RL illustrated in FIG. 6. This indicates that it takes a longer time for the plurality of polishing rates to converge. Furthermore, the polishing rate of a certain region hunts (fluctuates) after its change point. As a result, the pressure control of the polishing head 1 is not stabilized until the target film thickness is reached.

As can be seen from comparison between FIG. 6 and FIG. 8, the present embodiment in which the polishing-amount control operation is performed before the change point of the polishing rate can stabilize the profile control operation after the change point of the polishing rate.

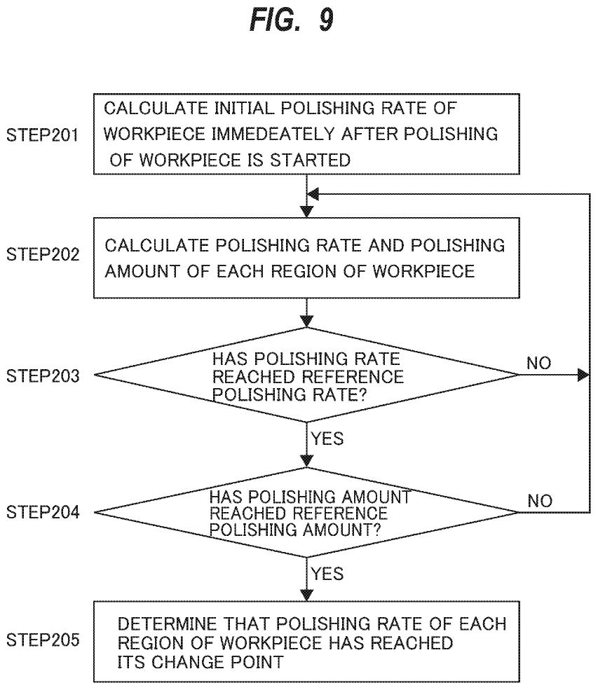

FIG. 9 is a flowchart illustrating an embodiment of step 104 in FIG. 4 for detecting the plurality of change points of the plurality of polishing rates.

In step 201, immediately after the start of polishing of the workpiece W, the polishing controller 9 calculates an initial polishing rate of the workpiece W. Since the polishing rate is an amount of decrease in film thickness of the workpiece W per unit time, the polishing controller 9 can calculate the initial polishing rate from the film thickness of the workpiece W measured by the film-thickness sensor 21.

In step 202, the polishing controller 9 calculates a current polishing rate and a current polishing amount of each of the plurality of regions of the workpiece W, thereby acquiring a plurality of current polishing rates and a plurality of current polishing amounts corresponding to the plurality of regions. The polishing amount of each region of the workpiece W is a difference between a film thickness at the start of polishing of the workpiece W and a film thickness at a current time.

In step 203, the polishing controller 9 determines whether or not the current polishing rate of each of the plurality of regions has reached a reference rate.

In one embodiment, the reference rate is a polishing rate determined based on the initial polishing rate calculated in the step 201. For example, the reference rate is obtained by multiplying the initial polishing rate by a reference ratio. The reference ratio is a reference value of a ratio of a polishing rate after a change point to a polishing rate before the change point.

In another embodiment, the reference rate may be a polishing rate obtained from a polishing result of a reference workpiece having the same surface structure. More specifically, the reference rate is a polishing rate of the reference workpiece after a change point of the polishing rate of the reference workpiece is detected.

When the current polishing rate has not reached the reference rate (NO in step 203), the process flow returns to step 202.

When the current polishing rate has reached the reference rate (YES in step 203), in step 204, the polishing controller 9 determines whether or not the current polishing amount of each of the plurality of regions of the workpiece W has reached a reference polishing amount. In one embodiment, the reference polishing amount is an amount of decrease in film thickness (i.e., a polishing amount) from the start of polishing of the reference workpiece until the change point of the polishing rate of the reference workpiece.

When the current polishing amount has not reached the reference polishing amount (NO in step 204), the process flow returns to step 202.

When the current polishing amount has reached the reference polishing amount (YES in step 204), in step 205, the polishing controller 9 determines that the plurality of polishing rates of the plurality of regions of the workpiece W have reached their change points. In this manner, the polishing controller 9 can detect the plurality of change points of the plurality of polishing rates.

Step 203 described above provides a first detection condition for detecting the plurality of change points of the plurality of polishing rates, and step 204 described above provides a second detection condition for detecting the plurality of change points of the plurality of polishing rates. In the embodiment illustrated in FIG. 9, the plurality of change points of the plurality of polishing rates are detected when both the first detection condition and the second detection condition are satisfied.

In another embodiment, either one of step 203 and step 204 described above may be omitted. In still another embodiment, step 203 described above may be performed after step 204.

Specifically, the plurality of change points of the plurality of polishing rates are detected when at least one of the first detection condition and the second detection condition is satisfied. The first detection condition is that each of the plurality of polishing rates reaches the reference rate, and the second detection condition is that the polishing amount of each of the plurality of regions of the workpiece W reaches the reference polishing amount.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing method comprising:
polishing a workpiece by pressing a surface of the workpiece against a polishing pad with a plurality of pressure chambers of a polishing head while measuring a film thickness of the workpiece;
during polishing of the workpiece, calculating a plurality of polishing rates of a plurality of regions within the surface of the workpiece; and
detecting a plurality of change points of the plurality of polishing rates,
wherein, before the plurality of change points of the plurality of polishing rates are detected, the polishing head performs a polishing-amount control operation of polishing the plurality of regions of the workpiece by the same polishing amount, and
wherein, after the plurality of change points of the plurality of polishing rates are detected, the polishing head performs a profile control operation of polishing the plurality of regions of the workpiece such that a film-thickness profile of the workpiece reaches a target film-thickness profile.

2. The polishing method according to claim 1, wherein the polishing-amount control operation includes polishing the plurality of regions of the workpiece by the polishing head such that a surface shape of the workpiece, indicated by an initial film-thickness profile at a start of polishing of the workpiece, is maintained.

3. The polishing method according to claim 1, wherein the plurality of change points of the plurality of polishing rates are detected when at least one of a first detection condition and a second detection condition is satisfied,
the first detection condition is that each of the plurality of polishing rates reaches a reference rate, and
the second detection condition is that a polishing amount of each of the plurality of regions of the workpiece reaches a reference polishing amount.

4. The polishing method according to claim 1, wherein the polishing-amount control operation is switched to the profile control operation after all of the plurality of change points of the plurality of polishing rates, corresponding respectively to the plurality of regions of the workpiece, are detected.

5. The polishing method according to claim 1, wherein the workpiece has a surface structure including a first film and a second film formed under the first film, and
the plurality of change points are points in time at which the first film is removed.

6. The polishing method according to claim 5, wherein a polishing rate of the first film is different from a polishing rate of the second film.

7. A polishing apparatus comprising:
a polishing table configured to support a polishing pad;
a polishing head having a plurality of pressure chambers configured to press a surface of a workpiece against the polishing pad;
a film-thickness sensor configured to measure a film thickness of the workpiece;
a pressure regulating device configured to regulate pressures in the plurality of pressure chambers; and
a polishing controller configured to perform pressure control of the polishing head by controlling operation of the pressure regulating device,
wherein the polishing controller is configured to:
calculate a plurality of polishing rates of a plurality of regions within the surface of the workpiece;
detect a plurality of change points of the plurality of polishing rates;
before detecting the plurality of change points of the plurality of polishing rates, instruct the pressure regulating device to cause the polishing head to perform a polishing-amount control operation of polishing the plurality of regions of the workpiece by the same polishing amount; and
after detecting the plurality of change points of the plurality of polishing rates, instruct the pressure regulating device to cause the polishing head to perform a profile control operation of polishing the plurality of regions of the workpiece such that a film-thickness profile of the workpiece reaches a target film-thickness profile.

8. The polishing apparatus according to claim 7, wherein the polishing controller is configured to:
create an initial film-thickness profile at a start of polishing of the workpiece from a plurality of measurement values of an initial film thickness of the workpiece; and
during the polishing-amount control operation, instruct the pressure regulating device to cause the polishing head to polish the plurality of regions of the workpiece such that a surface shape of the workpiece, indicated by the initial film-thickness profile, is maintained.

9. The polishing apparatus according to claim 7, wherein the polishing controller is configured to detect the plurality of change points of the plurality of polishing rates when at least one of a first detection condition and a second detection condition is satisfied,
the first detection condition is that each of the plurality of polishing rates reaches a reference rate, and
the second detection condition is that a polishing amount of each of the plurality of regions of the workpiece reaches a reference polishing amount.

10. The polishing apparatus according to claim 7, wherein the polishing controller is configured to switch the pressure control of the polishing head from the polishing-amount control operation to the profile control operation after all of the plurality of change points of the plurality of polishing rates, corresponding respectively to the plurality of regions of the workpiece, are detected.

11. The polishing apparatus according to claim 7, wherein the workpiece has a surface structure including a first film and a second film formed under the first film, and
the plurality of change points are points in time at which the first film is removed.

12. The polishing apparatus according to claim 11, wherein a polishing rate of the first film is different from a polishing rate of the second film.
